(19) United States
(12) Patent Application Publication
(10) Pub. No.: US 2013/0193413 A1
(43) Pub. Date: Aug. 1, 2013

(54) STACKING STRUCTURE, ORGANIC SEMICONDUCTOR DEVICE, WIRING, AND DISPLAY, AND METHOD OF MANUFACTURING ORGANIC SEMICONDUCTOR DEVICE

(71) Applicant: Ryuto Akiyama, Kanagawa (JP)

(72) Inventor: Ryuto Akiyama, Kanagawa (JP)

(73) Assignee: SONY CORPORATION, Tokyo (JP)

(21) Appl. No.: 13/616,286

(22) Filed: Sep. 14, 2012

(30) Foreign Application Priority Data
Oct. 18, 2011 (JP) 2011-228837

(51) Int. Cl. H01L 51/10; H01L 51/40

(52) U.S. Cl. 257/40; 257/741; 438/99; 257/E51.005; 257/E51.02

(57) ABSTRACT

A stacked structure including an organic layer; a conductor or a semiconductor layer; a protective layer made of an insulating material and covering at least a part of a top surface or an undersurface of the organic layer; and a plurality of grains an outside of each of which is covered with an affinity layer that has an affinity with the insulating material, the plurality of grains being dispersed in the protective layer.

### BACKGROUND

The technology relates to a stacking structure having a protective layer on an organic layer, and applicable to a transistor, a wiring, and the like, for example. The technology also relates to an organic semiconductor device, a wiring, and a display each having the stacking structure, as well as a method of manufacturing the organic semiconductor device.

Organic transistors using organic semiconductor materials have been attracting attention, because these transistors are capable of being produced at low cost and have high flexibility. For instance, when the organic transistors are each used as a drive device of a display and wirings are also each configured of an organic conductor, it is possible to increase flexibility of the entire display.

An organic semiconductor layer of such an organic transistor is capable of being formed by, for example, coating or printing. Both the coating and the printing are carried out using ink in which an organic semiconductor material is dissolved in an organic solvent. Both the coating and the printing are allowed to be readily performed at a low temperature and therefore, detailed studies thereof have been pursued.

The organic semiconductor material is allowed to be readily used by being mixed with the organic solvent as mentioned above, but there is such a disadvantage that chemical resistance thereof is low. For instance, when a display is produced using an organic transistor, an insulating layer and electrodes are formed after formation of an organic semiconductor layer. In a process of forming the insulating layer and the electrodes, an organic liquid or gas is used. This organic liquid or gas may cause deterioration of the organic semiconductor layer, leading to degradation in properties of the organic transistor. In order to prevent such deterioration in a manufacturing process, a protective layer is provided on the organic semiconductor layer. It has been suggested to make an improvement to a barrier property by causing this protective layer to contain grains, as described in Japanese Unexamined Patent Application Publication No. 2008-4817, for example.

### SUMMARY

In the protective layer thus containing the grains, however, the grains are not uniformly mixed in the ink containing the insulating material and the solvent, when the protective film is formed by the coating or printing. In other words, the grains are in a low dispersion state. Such a protective layer with poor uniformity has a disadvantage that the barrier property deteriorates.

It is desirable to provide a stacking structure in which a barrier property is improved by uniformly dispersing grains in a protective layer. It is also desirable to provide an organic semiconductor device, a wiring, and a display each having this stacking structure, as well as a method of manufacturing the organic semiconductor device.

According to an embodiment of the technology, there is provided a stacking structure including: an organic layer including a conductor or a semiconductor; a protective layer configured of an insulating material, and covering at least a part of a top surface or an undersurface of the organic layer; and a plurality of grains each of whose outside is covered with an affinity layer that has an affinity with the insulating material, the plurality of grains being dispersed in the protective layer.

According to an embodiment of the technology, there is provided an organic semiconductor device including a stacking structure, the stacking structure including: an organic layer including a semiconductor; a protective layer configured of an insulating material, and covering at least a part of a top surface or an undersurface of the organic layer; and a plurality of grains each of whose outside is covered with an affinity layer that has an affinity with the insulating material, the plurality of grains being dispersed in the protective layer.

According to an embodiment of the technology, there is provided a wiring including a stacking structure, the stacking structure including: an organic layer including a conductor; a protective layer configured of an insulating material, and covering at least a part of a top surface or an undersurface of the organic layer; and a plurality of grains each of whose outside is covered with an affinity layer that has an affinity with the insulating material, the plurality of grains being dispersed in the protective layer.

According to an embodiment of the technology, there is provided a display including a plurality of pixels and an organic semiconductor device driving the plurality of pixels, the organic semiconductor device including: a gate electrode; an organic layer facing the gate electrode, and including a semiconductor; source-drain electrodes electrically connected to the organic layer; a protective layer configured of an insulating material, and covering the organic layer; and a plurality of grains each of whose outside is covered with an affinity layer that has an affinity with the insulating material, the plurality of grains being dispersed in the protective layer.

According to an embodiment of the technology, there is provided a method of manufacturing an organic semiconductor device, the method including: forming an organic layer including a semiconductor; preparing ink by mixing an insulating material and grains into a solvent; and forming a protective layer by covering the organic layer with the ink, wherein outside of each of the grains is covered with an affinity layer that has an affinity with the insulating material.

In the stacking structure, the organic semiconductor device, the wiring, and the display, as well as the method of manufacturing the organic semiconductor device according to the embodiments of the technology, the affinity layer is provided on the outside of each of the grains. This increases the affinity between each of the grains and the insulating material as well as the solvent, when the protective layer is formed. Thus, the grains are uniformly dispersed.

According to the stacking structure, the organic semiconductor device, the wiring, and the display, as well as the method of manufacturing the organic semiconductor device in the embodiments of the technology, the affinity layer is provided on the outside of each of the grains. This allows the grains to be uniformly dispersed in the protective layer, and thereby an improvement in barrier property is allowed. Therefore, deterioration of the organic layer in a manufacturing process is prevented, which allows an improvement in reliability.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a cross-sectional diagram illustrating a basic structure according to an embodiment of the technology.

FIG. 2 is a cross-sectional diagram illustrating a configuration of an organic TFT (Thin Film Transistor) according to a first embodiment of the disclosure.

FIG. 3 is a cross-sectional diagram illustrating a configuration of one of grains illustrated in FIG. 1.

FIG. 4 is a flow chart illustrating a manufacturing process of the organic TFT illustrated in FIG. 1.

FIG. 5 is a cross-sectional diagram illustrating a configuration of an organic TFT according to a modification 1.

FIG. 6 is a cross-sectional diagram illustrating a configuration of an organic TFT according to a modification 2.

FIG. 7 is a cross-sectional diagram illustrating a configuration of an organic TFT according to a modification 3.

FIG. 8 is a cross-sectional diagram illustrating a configuration of a wiring according to a second embodiment of the disclosure.

FIG. 9 is a diagram illustrating a circuit configuration of a display according to an application example 1.

FIG. 10 is an equivalent circuit schematic illustrating an example of a pixel driving circuit illustrated in FIG. 9.

FIGS. 11A and 11B are perspective diagrams each illustrating an appearance of an application example 2.

FIG. 12 is a perspective diagram illustrating an appearance of an application example 3.

FIGS. 13A and 13B are perspective diagrams of an application example 4, namely, FIG. 13A illustrates an appearance viewed from front, and FIG. 13B illustrates an appearance viewed from back.

FIG. 14 is a perspective diagram illustrating an appearance of an application example 5.

FIG. 15 is a perspective diagram illustrating an appearance of an application example 6.

FIGS. 16A to 16G are views of an application example 7, namely, a front view in an open state, a side view in the open state, a front view in a closed state, a left-side view, a right-side view, a top view, and a bottom view, respectively.

### DETAILED DESCRIPTION

Embodiments of the technology will be described below in detail with reference to the drawings. It is to be noted that the description will be provided in the following order.
1. Basic structure
2. First embodiment

An example in which a protective layer is provided in an organic TFT of a bottom-contact/bottom-gate type.
3. Modification 1

An example in which a protective layer is provided in an organic TFT of a top-contact/bottom-gate type.
4. Modification 2

An example in which a protective layer is provided in an organic TFT of a top-gate type.
5. Modification 3

An example of an organic TFT in which a protective layer serves as a planarizing layer.
6. Second embodiment

An example in which a protective layer is provided in a wiring.

### Basic Structure

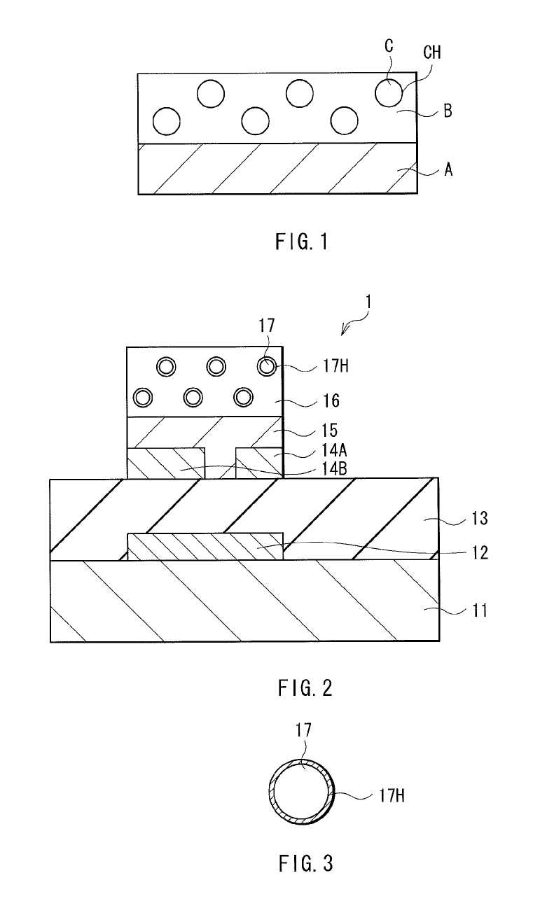

A stacking structure according an embodiment of the technology includes an organic layer A and a protective layer B, as illustrated in FIG. 1. The organic layer A includes a conductor or a semiconductor, and the protective layer B covers this organic layer A. The protective layer B is made of an insulating material, and a plurality of grains C are dispersed in the protective layer B. The outside of each of the grains C is covered with an affinity layer CH having an affinity with the insulating material of the protective layer B. Such a stacking structure according to the embodiment of the technology is applied to, for example, an organic semiconductor device such as an organic TFT (an organic TFT 1 to be described later) and a wiring (a wiring 2 to be described later).

### First Embodiment

FIG. 2 illustrates a cross-sectional configuration of an organic TFT (the organic TFT 1) according to a first embodiment of the disclosure. The organic TFT 1 is a field effect transistor, and used as a drive device of a display that uses a display body of a liquid crystal type, an organic EL type, or an electrophoretic type. The organic TFT 1 has a bottom-contact/bottom-gate structure. The organic TFT 1 includes a gate electrode 12, a gate insulating film 13, source-drain electrodes 14A and 14B, an organic semiconductor layer 15 (an organic layer), and a protective layer 16 in this order on a substrate 11.

The substrate 11 is configured of, for example, a glass substrate, a quartz substrate, a plastic film, or the like, having a thickness of about 20 nm to about 1 mm. For the plastic film, there may be used, for example, a material such as polyethylene terephthalate, polyethylene naphthalate, polyether sulfone, polyetherimide, polyetheretherketone, polyether ketone, polyphenylene sulfide, polyarylate, polyimide, polycarbonate, cellulose triacetate, a cycloolefin polymer, polyolefin, polyvinyl chloride, a liquid crystal polymer, an epoxy resin, a phenolic resin, a urea resin, a melamine resin, and a silicon resin. These resins may be used in combination. When the substrate 11 is configured of the plastic film, flexibility of the organic TFT1 improves. When the substrate 11 is configured of an inorganic substance such as the glass substrate or the quartz substrate, a surface (a surface on the gate electrode 12 side) is covered with an organic insulating film made of a polymer material. The organic insulating film is made of, for example, polyvinyl phenol, polymethyl methacrylate, or a mixture of polyvinyl phenol and octadecyl trichlorosilane. Such an organic insulating film may be adhered to the glass substrate or the quartz substrate, or may be formed by coating.

The gate electrode 12 serves to control a carrier density in the organic semiconductor layer 15, by applying a gate voltage to the organic TFT 1. The gate electrode 12 is provided to face the organic semiconductor layer 15. The gate electrode 12 is provided in a selective region on the substrate 11. The gate electrode 12 is configured of, for example, a simple metal such as gold (Au), silver (Ag), platinum (Pt), titanium (Ti), ruthenium (Ru), molybdenum (Mo), copper (Cu), tungsten (W), chromium (Cr), nickel (Ni), aluminum (Al), palladium (Pd), iron (Fe), manganese (Mn), and tantalum (Ta), or an alloy of any of these metals. An inorganic conductive material other than those described above, or an organic conductive material such as polyaniline, or a carbon material may be used for the gate electrode 12. The gate electrode 12 has a thickness of, for example, about 50 nm to about 200 nm.

The gate insulating film 13 is provided between the gate electrode 12 and the source-drain electrodes 14A and 14B to insulate the gate electrode 12 and the source-drain electrodes 14A and 14B from each other. The gate insulating film 13 is configured of, for example, an organic material such as polyvinyl phenol, polymethyl methacrylate, polyvinyl alcohol, polyimide, polyamide, polyester, polyvinyl acetate, polyurethane, polysulfone, a polyvinylidene fluoride, cyanoethyl pullulan, epoxy resin, phenolic resin, benzocyclobutene resin, and acrylic resin. An inorganic material such as a silicon oxide (SiO₂), an aluminum oxide (Al₂O₃), and a tantalum oxide (Ta₂O₅) may be used for the gate insulating film 13. The gate insulating film 13 has a thickness of, for example, about 50 nm to about 1,000 nm.

The source-drain electrodes 14A and 14B are provided on the gate insulating film 13, so that a space between the source-drain electrode 14A and the source-drain electrode 14B faces the gate electrode 12. The source-drain electrodes 14A and 14B are electrically connected to the organic semiconductor layer 15. The source-drain electrodes 14A and 14B are configured of a material similar to that of the gate electrode 12, and each have a thickness of, for example, about 50 nm to about 200 nm.

The organic semiconductor layer 15 is provided on the source-drain electrodes 14A and 14B, as well as in the space between these electrodes. Examples of the material forming the organic semiconductor layer 15 include: polythiophene, poly-3-hexylthiophene [P3HT] formed by introducing a hexyl group into polythiophene, pentacene[2,3,6,7-dibenzanthracene], polyanthracene, naphthacene, hexacene, heptacene, dibenzopentacene, tetrabenzopentacene, chrysene, perylene, coronene, terylene, ovalene, quaterrylene, circumanthracene, benzopyrene, dibenzopyrene, triphenylene, polypyrrole, polyaniline, polyacetylene, polydiacetylene, polyphenylene, polyfuran, polyindole, polyvinylcarbazole, polyselenophene, polytellurophene, polyisothianaphthene, polycarbazole, polyphenylene sulfide, polyphenylene vinylene, polyvinylene sulphide, polythienylene vinylene, polynaphthalene, polypyrene, polyazulene, phthalocyanine represented by copper phthalocyanine, merocyanine, hemicyanine, polyethylenedioxythiophene, pyridazine, naphthalenetetracarboxylic acid diimide, poly(3,4-ethylenedioxythiophene)/poly(styrenesulfonate) [PEDOT/PSS], 4,4′-biphenyl dithiol (BPDT), 4,4′-diisocyanobiphenyl, 4,4′-diisocyano-p-terphenyl, 2,5-bis(5′-thioacetyl-2′-thiophenyl)thiophene, 2,5-bis(5′-thioacetoxyl-2′-thiophenyl)thiophene, 4,4′-diisocyanophenyl, benzidine(biphenyl-4,4′-diamine), TCNQ (tetracyanoquinodimethane), a charge-transfer complex represented by a tetrathiafulvalene (TTF)-TCNQ complex, a bisethylenetetrathiafulvalene (BEDTTTF)-perchloric acid complex, a BEDTTTF-iodine complex, and a TCNQ-iodine complex, a biphenyl-4,4′-dicarboxylic acid, 1,4-di(4-thiophenylacetylinyl)-2-ethylbenzene, 1,4-di(4-isocyanophenylacetylinyl)-2-ethylbenzene, dendrimer, fullerene such as C60, C70, C76, C78, and C84, 1,4-di(4-thiophenylethynyl)-2-ethylbenzene, 2,2″-dihydroxy-1,1′:4′,1″-terphenyl, 4,4′-biphenyl diethanal, 4,4′-biphenyldiol, 4,4′-biphenyldiisocyanate, 1,4-diasetynylbenezene, diethylbiphenyl-4,4′-dicarboxylate, benzo[1,2-c; 3,4-c′; 5,6-c″]tris[1,2]dithiol-1,4,7-trithione, alpha-sexithiophene, tetrathiotetracene, tetraselenotetracene, tetratellurium tetracene, poly(3-alkylthiophene), poly(3-thiophene-β-ethanesulfonic acid), poly(N-alkyl pyrrole), poly(3-alkyl pyrrole), poly(3,4-dialkylpyrrole), poly(2,2′-thienylpyrrole), poly(dibenzothiophene sulfide), and quinacridone. In addition, materials such as a condensed polycyclic aromatic compound, a porphyrin-based derivative, a phenylvinylidene-based conjugated oligomer, and a thiophene-based conjugated oligomer may be used. The organic semiconductor layer 15 has a thickness of, for example, about 10 nm to about 100 nm.

The protective layer 16 protects the organic semiconductor layer 15 from chemical or physical shock in a manufacturing process and during operation, and covers a top surface of the organic semiconductor layer 15. The protective layer 16 may cover an undersurface of the organic semiconductor layer 15, or may cover at least a part of the top surface or the undersurface of the organic semiconductor layer 15. The protective layer 16 may cover the top surface and a side face of the organic semiconductor layer 15. The protective layer 16 is configured of an insulating material capable of maintaining a shape, e.g., a resin. It is preferable that a fluorine-containing resin of high chemical resistance be used for the protective layer 16, in order to prevent the organic semiconductor layer 15 from deteriorating due to chemicals (e.g., an organic liquid) and gas used in the manufacturing process. The protective layer 16 is made of, for example, a condensed fluorine-containing polymer such as a fluorine-containing polyimide, a fluorine-containing acrylic resin, a fluorine-containing ether polymer, or a fluorine-containing cyclic ether polymer. Any of these resins may be a perfluoro resin. Alternatively, chlorine may substitute for a fluorination residue (an unfluorinated part) of the fluorine-containing resin. It is preferable that the protective layer 16 have a thickness of 500 nm or more, e.g. about 500 nm to about 1 μm. This is to improve a barrier property of the protective layer 16.

The protective layer 16 contains, for example, about 1 wt % to about 50 wt % of grains 17. Each of the grains 17 is a spherical fine particle, and it is preferable that the particle size thereof be, for example, about 10 nm to about 1000 nm. When the particle size of the grain 17 exceeds 1,000 nm, formation of the protective layer 16 by coating or printing may be adversely affected, and also, dispersibility of the grains 17 in the protective layer 16 may deteriorate. The grains 17 are configured of resin fine particles such as polystyrene, polyethylene, polypropylene, polyvinyl alcohol, polyamide, polymethacrylate, and latex. Alternatively, the grains 17 are configured of inorganic fine particles such as glass, a silicon compound such as quartz and silica (SiO₂), magnesia, titania, zirconia, alumina (Al₂O₃), and apatite. It is preferable to use, for example, a material of a low dielectric constant such as polystyrene and polyethylene, as the material of the grains 17. This is because variations in threshold voltage due to a back channel effect of the organic TFT 1 are allowed to be suppressed. In the present embodiment, the outside (the surface) of the grain 17 is covered with an affinity layer 17H, as illustrated in FIG. 3.

The affinity layer 17H has a high affinity with the insulating material of the protective layer 16, and disperses the grains 17 in the protective layer 16 uniformly. For example, when the protective layer 16 is made of the fluorine-containing resin described above, the affinity layer 17H is made of a fluorinated functional group which is chemically connected to the grain 17. This fluorinated functional group is, for example, a fluorinated alkyl group; ether, ester, and an amide group having a fluorinated alkyl group; a fluorinated aryl group; or the like. The above-described fluorine-containing resin may be used as the material of the affinity layer 17H, and the grain 17 may be coated with this fluorine-containing resin. It is preferable that the affinity layer 17H be a functional group or resin with a high fluorination rate, in order to improve the dispersibility of the grains 17 in the protective layer 16. Further, it is preferable that the affinity layer 17H have a fluoridation rate of about 60% or more.

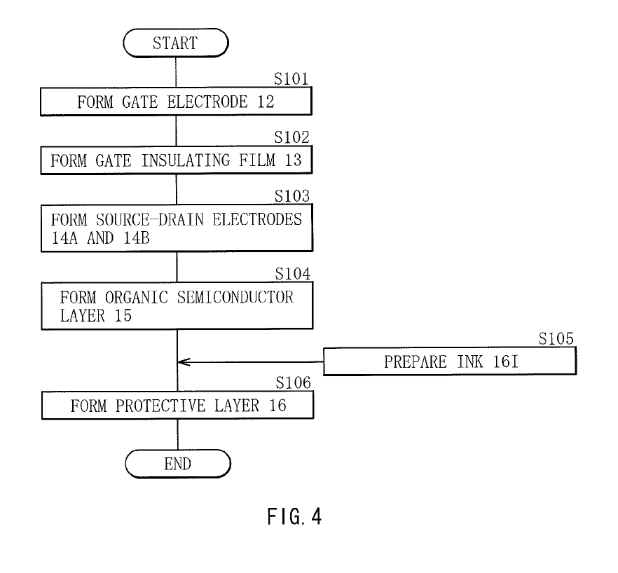

The organic TFT 1 may be manufactured as follows, for instance (FIG. 4).

First, the gate electrode 12 is formed on the substrate 11 (S101). For example, the gate electrode 12 is formed by patterning a film of gold using photolithography, after the film is formed over the entire surface of the substrate 11 by vacuum deposition. The gate electrode 12 may be formed by coating, printing, or plating.

Next, the gate insulating film 13 is formed to cover the gate electrode 12 (S102). For example, the gate insulating film 13 is formed by undergoing a heat treatment of 150 degrees, after a PGMEA (Propylene Glycol Monomethyl Ether Acetate) solution of polyvinyl phenol is applied onto the gate electrode 12 as well as onto the substrate 11 by spin coating. On this gate insulating film 13, the source-drain electrodes 14A and 14B made of gold are formed in a way similar to that of the gate electrode 12, for example (S103).

After the source-drain electrodes 14A and 14B are formed, the organic semiconductor layer 15 is formed on the source-drain electrodes 14A and 14B, as well as in the space between the source-drain electrode 14A and the source-drain electrode 14B (S104). The organic semiconductor layer 15 is formed using, for example, a xylene solution of TIPS pentacene (6,13-Bis(triisopropylsilylethynyl)pentacene), by ink jetprinting.

Next, ink 16I used to form the protective layer 16 is prepared (S105). Specifically, for example, an amorphous fluororesin CYTOP (registered trademark) (manufactured by Asahi Glass Co., Ltd.) is used as the insulating material of the protective layer 16. First, 8 wt % of this amorphous fluororesin CYTOP is dissolved in (mixed into) a solvent. As the solvent used here, there may be used a solvent in which a fluorine-containing resin is soluble, and which prevents the organic semiconductor layer 15 from dissolving and also does not react with the organic semiconductor layer 15. For example, a fluorine-containing-based solvent such as CT180 and CT100 (manufactured by Asahi Glass Co., Ltd.) may be used. In addition to these, organic solvents such as fluorine-containing aliphatic hydrocarbons, fluorine-containing ethers, and fluorine-containing alkyl amines may be used. A solution in which a fluorination residue is partially substituted with chlorine may be used, or a mixture of two or more kinds may be used. Water or any of alcohols may be used as the solvent that causes the insulating material to be dissolved, but in this case, a high-polarity insulating material is selected.

Meanwhile, the affinity layer 17H is formed on the outside of each of the grains 17. For example, a polystyrene bead having a diameter of 50 nm and modified by an amino group is used for the grain 17, and the affinity layer 17H made of a perfluorooctyl group is caused to form a chemical bond on the surface of the grain 17. The perfluorooctyl group is introduced by, for example, causing dehydration synthesis with the addition of 10 wt % of a hydrofluoroether solution of a perfluorooctane acid to the polystyrene bead, thereby producing an amide bond between the amino group and the perfluorooctane acid of the polystyrene bead. In addition, when the grain 17 is, for instance, the resin fine particle or the inorganic fine particle having a surface modified by a hydroxyl group, the affinity layer 17H is introduced by using a silane coupling agent (e.g., chlorosilane, alcoxysilane, or the like) having a fluorine-containing functional group such as a fluorinated alkyl group, a fluorinated alkylether group, and a fluorinated aryl group. When the grain 17 is, for example, the resin fine particle having a surface modified by a carboxyl group or a sulfone group, the affinity layer 17H is introduced by using an amine having the fluorine-containing functional group. When the grain 17 is, for instance, the resin fine particle having a surface modified by an amino group, the affinity layer 17H is introduced by using a carboxylic acid or a sulfonic acid having the fluorine-containing functional group. The affinity layer 17H is also allowed to be introduced in a similar manner, when being made of a fluorine-containing resin. After being extracted, the solution containing the grains 17 each having the formed affinity layer 17H is subjected to drying under reduced pressure. 2 wt % of powder obtained by this drying under reduced pressure is added to the solution containing the insulating material of the protective layer 16, and thereby the ink 16I is prepared. At this moment, in the present embodiment, the outside of each of the grains 17 is provided with the affinity layer 17H and thus, the grains 17 are uniformly dispersed in the ink 16I.

In Japanese Unexamined Patent Application Publication No. 2008-4817, the grains are mixed in the protective layer to improve the barrier property. However, because no affinity layer is provided on the outside of each of the grains, the grains precipitate or float on the surface without being uniformly dispersed in the ink. This is because the specific gravity of the grains is different from that of the solvent contained in the ink, and also, because the grains are insoluble in this solvent and has a low affinity therefor. When the protective layer is formed using this ink, the dispersibility of the grains in the protective layer is low, and an expected sufficient barrier effect is not achieved. When, in particular, a fluorine-containing resin is used as the insulating material of the protective layer and this is dissolved in a fluorine-containing-based solvent, it is difficult to increase the thickness of the protective layer because of a low surface tension of the fluorine-containing-based solvent, and thereby the barrier property deteriorates.

Further, because a silicon oxide (SiO₂) having a high dielectric constant is used as the material of the grains, variations in threshold voltage may occur due to a back channel effect when the organic TFT is operated, which leads to deterioration in reliability.

In the organic TFT 1, in contrast, the outside of each of the grains 17 dispersed in the protective layer 16 is covered with the affinity layer 17H. This increases the affinity between the grains 17 and the insulating material as well as the solvent in the ink 16I and thus, the grains 17 are uniformly dispersed. In other words, the grains 17 are uniformly dispersed in the protective layer 16, and a sufficient gas barrier effect is achieved. Further, since the thixotropy of the ink 16I improves, the thickness of the protective layer 16 is allowed to be increased even when the ink 16I is prepared using a fluorine-containing resin or a fluorine-containing-based solvent.

Furthermore, the material of the grains 17 is allowed to be selected without limitation to the affinity between the grains 17 and the insulating material as well as the solvent. Therefore, a material of a low dielectric constant, e.g., polystyrene or polyethylene, may be used for the grains 17.

After the ink 16I is prepared, this ink 16I is formed and then dried on the organic semiconductor layer 15 by coating or printing, which completes the protective layer 16 (S106). Examples of the coating include spin coating, slit coating, dip coating, roll coating, bar coating, and slit & spin coating. As the printing, ink-jet printing, screen printing, flexographic printing, and reverse offset printing may be used. The printing allows an increase in film thickness and enables high-definition printing, by increasing the thixotropy of the ink 16I as described above. For example, the protective layer 16 is allowed to be formed by being dried at 120° C. for ten minutes, after the ink 16I is printed on the organic semiconductor layer 15 by the reverse offset printing. The organic TFT 1 illustrated in FIG. 2 is completed by going through the above-described process.

When a gate voltage of a predetermined threshold voltage or higher is applied to the gate electrode 12 in the organic TFT 1, a channel is formed in the organic semiconductor layer 15, and a current (a drain current) flows between the source-drain electrodes 14A and 14B. Thereby, the organic TFT 1 functions as a transistor. Here, since the outside of each of the grains 17 is provided with the affinity layer 17H, the grains 17 are uniformly dispersed in the protective layer 16. This increases the barrier property of the protective layer 16, thereby allowing the organic semiconductor layer 15 to be prevented from deteriorating in the manufacturing process as well as during the operation. Therefore, the reliability of the organic TFT 1 improves.

In addition, since a material of a low dielectric constant is allowed to be used for the grains 17, suppression of variations in the threshold voltage due to the back channel effect is enabled.

In the organic TFT 1 of the present embodiment, since the affinity layer 17H is provided on the outside of each of the grains 17, the dispersibility of the grains 17 in the protective layer 16 is allowed to be improved. Therefore, an improvement in the barrier property of the protective layer 16 is allowed.

Now, modifications and another embodiment of the technology will be described below. The same elements as those of the above-described embodiment will be provided with the same characters as those of the above-described embodiment, and the description thereof will be omitted.

### Modification 1

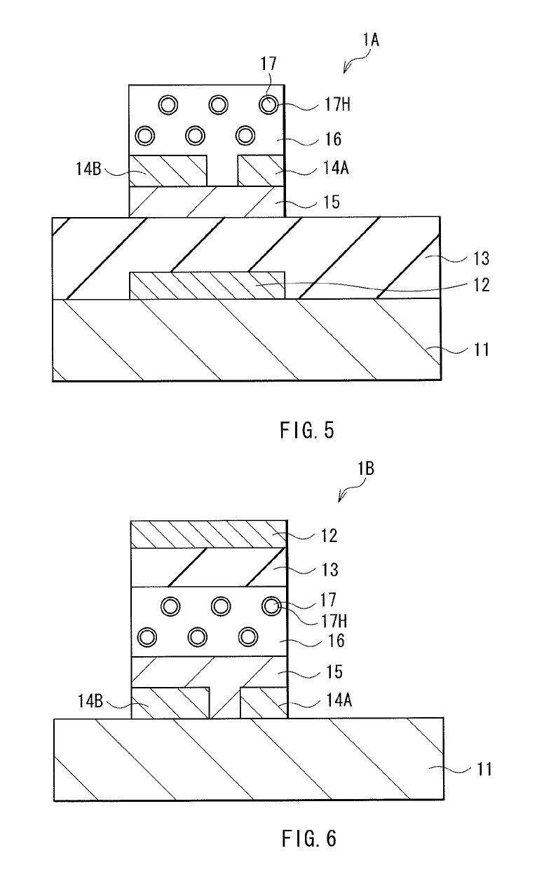

FIG. 5 illustrates a cross-sectional configuration of an organic TFT (an organic TFT 1A) according to a modification 1 of the first embodiment. This organic TFT 1A includes the gate electrode 12, the gate insulating film 13, the organic semiconductor layer 15, the source-drain electrodes 14A and 14B, and the protective layer 16 in this order on the substrate 11. In other words, the organic TFT 1A has a top-contact/bottom-gate type structure. Otherwise, the organic TFT 1A has a configuration, a function, and effects similar to those of the organic TFT 1.

### Modification 2

FIG. 6 illustrates a cross-sectional configuration of an organic TFT (an organic TFT 1B) according to a modification 2 of the first embodiment. This organic TFT 1B includes the source-drain electrodes 14A and 14B, the organic semiconductor layer 15, the protective layer 16, the gate insulating film 13, and the gate electrode 12 in this order on the substrate 11. In other words, the organic TFT 1B has a top-gate type structure. Otherwise, the organic TFT 1B has a configuration, a function, and effects similar to those of the organic TFT 1.

### Modification 3

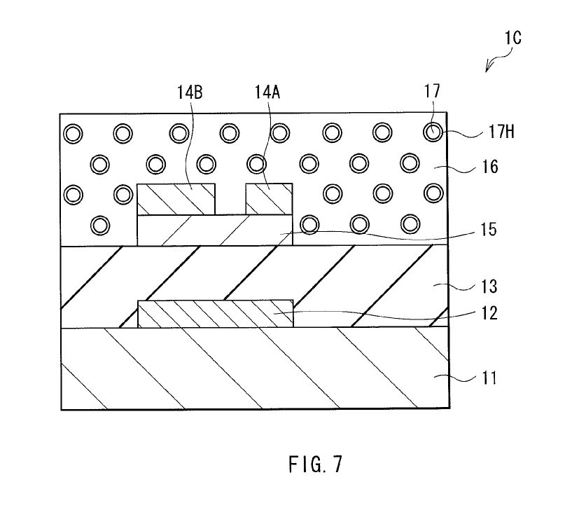

FIG. 7 illustrates a cross-sectional configuration of an organic TFT (the organic TFT 1C) according to a modification 3 of the first embodiment. In this organic TFT 1C, the protective layer 16 is provided not only on the organic semiconductor layer 15 and the source-drain electrodes 14A and 14B, but on the gate insulating film 13. In other words, here, the protective layer 16 serves as a planarizing layer. Otherwise, the organic TFT 1C has a configuration, a function, and effects similar to those of the organic TFT 1.

### Second Embodiment

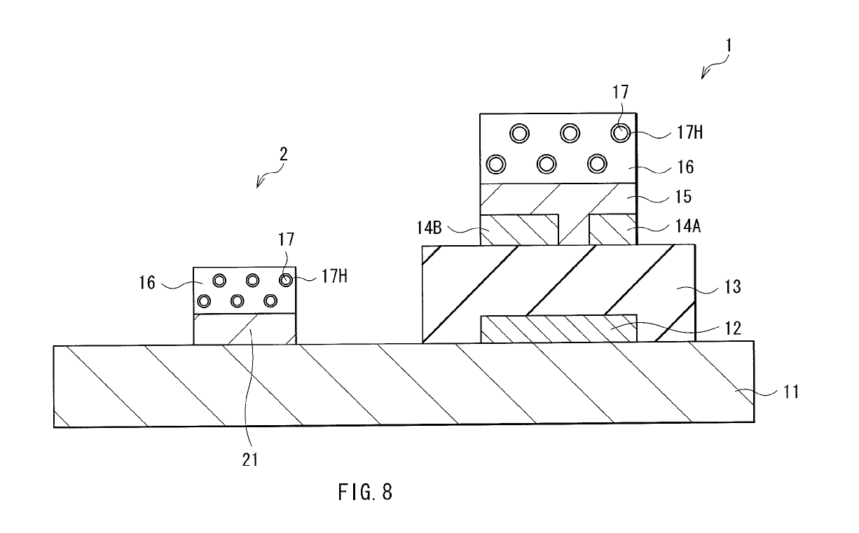

FIG. 8 illustrates a cross-sectional configuration of the wiring (the wiring 2) according to the second embodiment of the technology, together with the organic TFT 1. An electric signal is transmitted to the organic TFT 1 via this wiring 2.

In the wiring 2, an organic conductor layer 21 (an organic layer) and a protective layer 16 are laminated in this order from the substrate 11 side. The organic conductor layer 21 is configured of, for example, polyaniline or the like doped with PEDOT/PSS or an impurity.

The protective layer 16 protects the organic conductor layer 21 from physical and chemical shock in a manner similar to the first embodiment, and covers a surface (a top surface) of the organic conductor layer 21. Grains 17 are dispersed in the protective layer 16, and the outside of each of the grains 17 is provided with an affinity layer 17H. The protective layer 16 has a configuration, a function, and effects similar to those in the first embodiment.

### Application Example 1

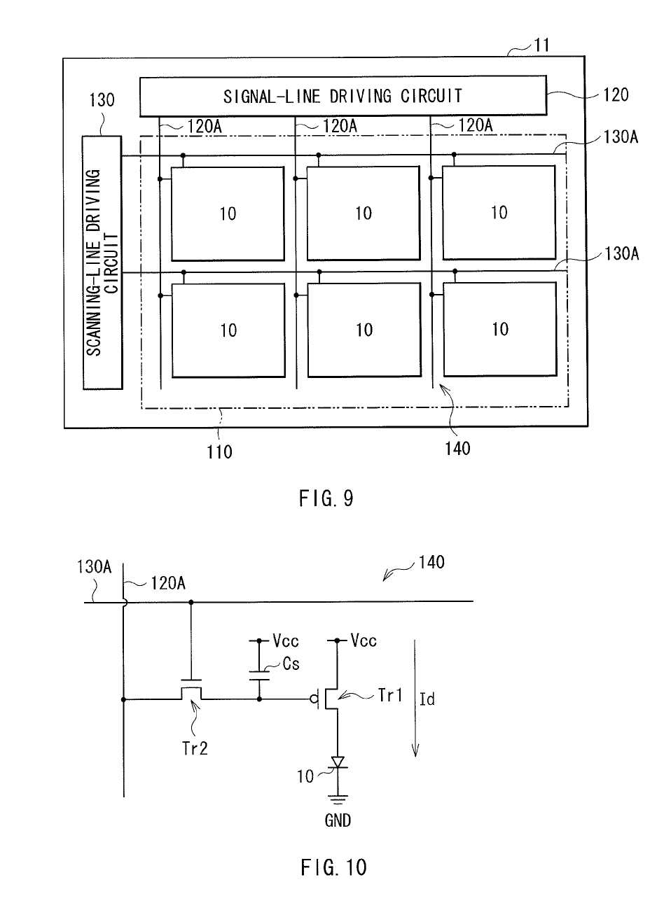

FIG. 9 illustrates a circuit configuration of a display having the organic TFT 1 (or any of the organic TFTs 1A, 1B, and 1C) as a drive device. The display is, for example, a liquid crystal display, an organic EL display, electronic paper, or the like, and includes a plurality of pixels 10 disposed in a matrix, and various drive circuits driving the pixels 10. The pixels 10 and the drive circuits are formed in a display region 110 on the substrate 11. On the substrate 11, a signal-line driving circuit 120 and a scanning-line driving circuit 130 which are drivers for image display, and a pixel driving circuit 140 are disposed as the drive circuits, for example. A sealing panel not illustrated is adhered onto the substrate 11. The pixels 10 and the drive circuits are sealed by this sealing panel.

FIG. 10 is an equivalent circuit schematic of the pixel driving circuit 140. The pixel driving circuit 140 is an active-type drive circuit in which transistors Tr1 are Tr2 are each disposed as the organic TFT 1. Provided between the transistors Tr1 and Tr2 is a capacitor Cs. The pixel 10 is connected in series to the transistor Tr1, between a first power supply line (Vcc) and a second power supply line (GND). In the pixel driving circuit 140 thus configured, a plurality of signal lines 120A are arranged in a column direction and a plurality of canning lines 130A are arranged in a row direction. Each of the signal lines 120A or each of the scanning lines 130A may be configured using the wiring 2. Each of the signal lines 120A is connected to the signal-line driving circuit 120, and an image signal is supplied from this signal-line driving circuit 120 to a source electrode of the transistor Tr2 through the signal line 120A. Each of the scanning lines 130A is connected to the scanning-line driving circuit 130, and a scanning signal is sequentially supplied from this scanning-line driving circuit 130 to a gate electrode of the transistor Tr2 through the scanning line 130A. In this display, since the transistors Tr1 and Tr2 are each configured using the organic TFT1 of the first embodiment, high-quality display is enabled by satisfactory TFT properties of the transistors Tr1 and Tr2. The display may be mounted, for example, on an electronic unit according to each of application examples 2 to 7 which will be described below.

### Application Example 2

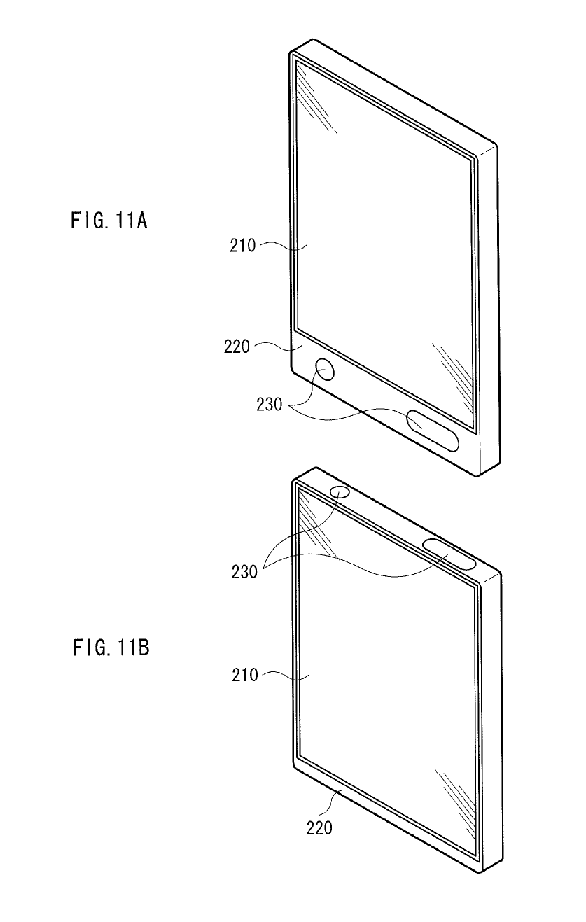

FIGS. 11A and 11B each illustrate an appearance of an electronic book. This electronic book includes, for example a display section 210, a non-display section 220, and an operation section 230. The operation section 230 may be formed either on the same surface as a surface (a front surface) of the display section 210 as illustrated in FIG. 11A, or on a surface (a top surface) different from the surface of the display section 210 as illustrated in FIG. 11B.

### Application Example 3

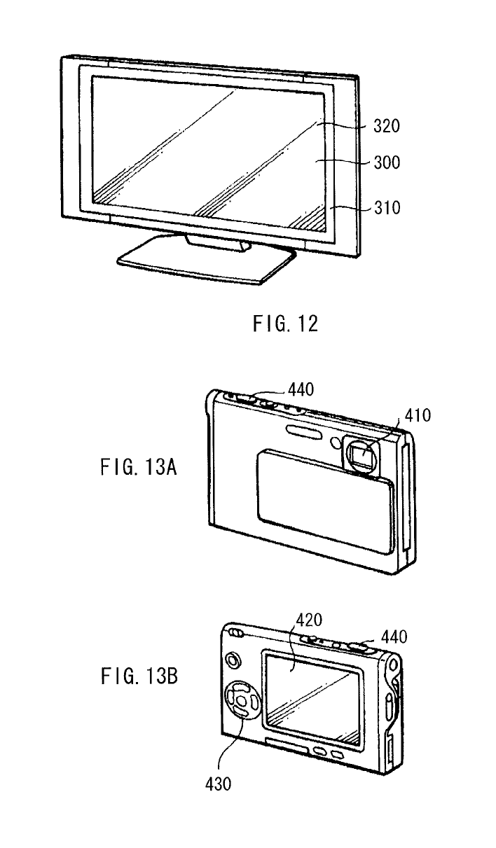

FIG. 12 illustrates an appearance of a television receiver. This television receiver has, for example, an image-display screen section 300 that includes a front panel 310 and a filter glass 320.

### Application Example 4

FIGS. 13A and 13B each illustrate an appearance of a digital camera. This digital camera includes, for example, a flash emitting section 410, a display section 420, a menu switch 430, and a shutter button 440.

### Application Example 5

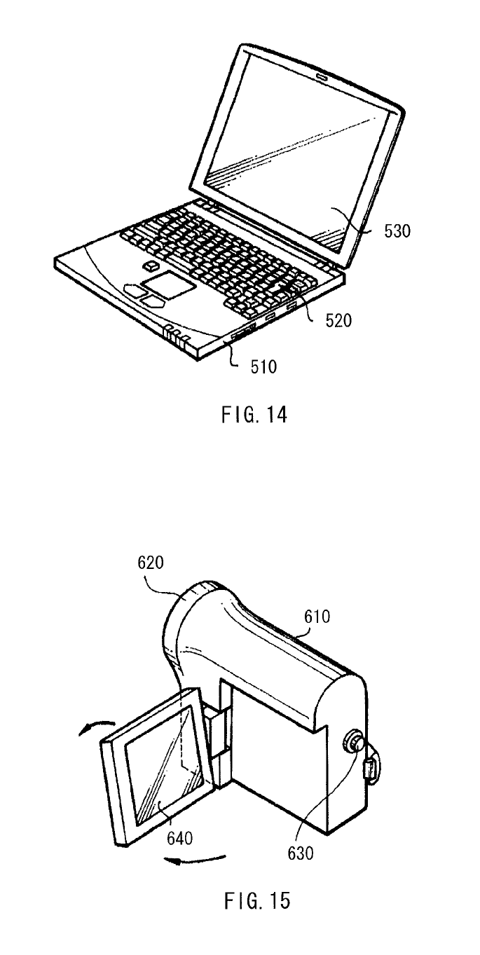

FIG. 14 illustrates an appearance of a laptop computer. This laptop computer includes, for example, a main body section 510, a keyboard 520 provided to enter characters and the like, and a display section 530 displaying an image.

### Application Example 6

FIG. 15 illustrates an appearance of a video camera. This video camera includes, for example, a main body section 610, a lens 620 disposed on a front face of this main body section 610 to shoot an image of a subject, a start/stop switch 630 used in shooting, and a display section 640.

### Application Example 7

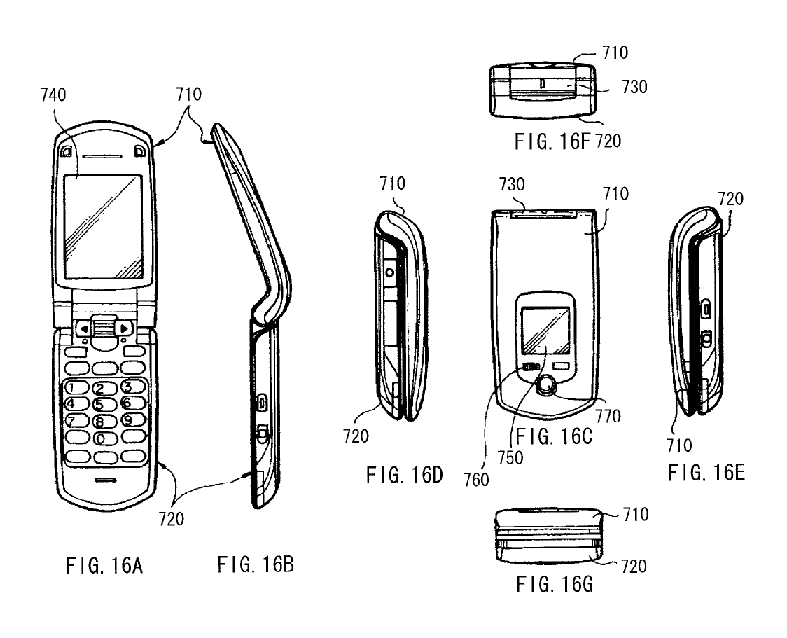

FIGS. 16A to 16G each illustrate an appearance of a portable telephone. This portable telephone is, for example, a unit in which an upper housing 710 and a lower housing 720 are connected by a coupling section (a hinge section) 730, and includes a display 740, a sub-display 750, a picture light 760, and a camera 770.

The technology has been described with reference to the embodiments and the modifications, but is not limited thereto and may be variously modified. For example, the grains 17 each having a spherical shape (FIG. 3) has been used in the embodiment, but each of the grains 17 may be in any other shape. For instance, each of the grains 17 may be shaped like a leaf, or a scale of a fish.

Further, the material and thickness of each layer, or the film formation methods and film formation conditions described in the embodiments and the modifications are not limited. Alternatively, other materials and thicknesses, or other film formation methods and film formation conditions may be adopted. For example, in the embodiments and the modifications, the protective layer 16 has been described as being made of the fluorine-containing resin. However, other resin material may be used for the protective layer 16.

Furthermore, in the embodiments and the modifications, the configuration of the organic TFT has been specifically described, but other layer may be further provided.

Moreover, in the second embodiment, the wiring 2 has been described as being used with the organic TFT 1, but the wiring 2 may be used with other transistor.

It is to be noted that the disclosure may be configured as follows.
(1) A stacking structure including:

an organic layer including a conductor or a semiconductor;

a protective layer configured of an insulating material, and covering at least a part of a top surface or an undersurface of the organic layer; and

a plurality of grains each of whose outside is covered with an affinity layer that has an affinity with the insulating material, the plurality of grains being dispersed in the protective layer.
(2) An organic semiconductor device including a stacking structure, the stacking structure including:

an organic layer including a semiconductor;

a protective layer configured of an insulating material, and covering at least a part of a top surface or an undersurface of the organic layer; and

a plurality of grains each of whose outside is covered with an affinity layer that has an affinity with the insulating material, the plurality of grains being dispersed in the protective layer.
(3) The organic semiconductor device according to (2), wherein the insulating material is a resin material.
(4) The organic semiconductor device according to (2) or (3), wherein the insulating material includes a fluorine-containing resin, and the affinity layer is configured of a fluorinated functional group forming a chemical bond with each of the grains.
(5) The organic semiconductor device according to (4), wherein the fluorinated functional group includes a perfluoroalkyl group.
(6) The organic semiconductor device according to (2) or (3), wherein the insulating material includes a fluorine-containing resin, and the affinity layer is a fluorine-containing resin covering each of the grains.
(7) The organic semiconductor device according to any one of (2) to (6), wherein the grains are configured of a resin.
(8) The organic semiconductor device according to any one of (2) to (7), wherein the grains are made of polystyrene.
(9) The organic semiconductor device according to any one of (2) to (6), wherein the grains are made of an inorganic substance.
(10) The organic semiconductor device according to any one of (2) to (9), including:

a gate electrode facing the organic layer; and

source-drain electrodes electrically connected to the organic layer.
(11) A wiring including a stacking structure, the stacking structure including:

an organic layer including a conductor;

a protective layer configured of an insulating material, and covering at least a part of a top surface or an undersurface of the organic layer; and

a plurality of grains each of whose outside is covered with an affinity layer that has an affinity with the insulating material, the plurality of grains being dispersed in the protective layer.
(12) A display including a plurality of pixels and an organic semiconductor device driving the plurality of pixels, the organic semiconductor device including:

a gate electrode;

an organic layer facing the gate electrode, and including a semiconductor;

source-drain electrodes electrically connected to the organic layer;

a protective layer configured of an insulating material, and covering the organic layer; and

a plurality of grains each of whose outside is covered with an affinity layer that has an affinity with the insulating material, the plurality of grains being dispersed in the protective layer.
(13) A method of manufacturing an organic semiconductor device, the method including:

forming an organic layer including a semiconductor;

preparing ink by mixing an insulating material and grains into a solvent; and

forming a protective layer by covering the organic layer with the ink,

wherein outside of each of the grains is covered with an affinity layer that has an affinity with the insulating material.

The disclosure contains subject matter related to that disclosed in Japanese Priority Patent Application JP 2011-228837 filed in the Japan Patent Office on Oct. 18, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A stacking structure comprising:
an organic layer including a conductor or a semiconductor;
a protective layer configured of an insulating material, and covering at least a part of a top surface or an undersurface of the organic layer; and
a plurality of grains each of whose outside is covered with an affinity layer that has an affinity with the insulating material, the plurality of grains being dispersed in the protective layer.

2. An organic semiconductor device including a stacking structure, the stacking structure comprising:
an organic layer including a semiconductor;
a protective layer configured of an insulating material, and covering at least a part of a top surface or an undersurface of the organic layer; and
a plurality of grains each of whose outside is covered with an affinity layer that has an affinity with the insulating material, the plurality of grains being dispersed in the protective layer.

3. The organic semiconductor device according to claim 2, wherein the insulating material is a resin material.

4. The organic semiconductor device according to claim 3, wherein the insulating material includes a fluorine-containing resin, and the affinity layer is configured of a fluorinated functional group forming a chemical bond with each of the grains.

5. The organic semiconductor device according to claim 4, wherein the fluorinated functional group includes a perfluoroalkyl group.

6. The organic semiconductor device according to claim 3, wherein the insulating material includes a fluorine-containing resin, and the affinity layer is a fluorine-containing resin covering each of the grains.

7. The organic semiconductor device according to claim 2, wherein the grains are configured of a resin.

8. The organic semiconductor device according to claim 2, wherein the grains are made of polystyrene.

9. The organic semiconductor device according to claim 2, wherein the grains are made of an inorganic substance.

10. The organic semiconductor device according to claim 2, comprising:
a gate electrode facing the organic layer; and
source-drain electrodes electrically connected to the organic layer.

11. A wiring including a stacking structure, the stacking structure comprising:
an organic layer including a conductor;
a protective layer configured of an insulating material, and covering at least a part of a top surface or an undersurface of the organic layer; and
a plurality of grains each of whose outside is covered with an affinity layer that has an affinity with the insulating material, the plurality of grains being dispersed in the protective layer.

12. A display including a plurality of pixels and an organic semiconductor device driving the plurality of pixels, the organic semiconductor device comprising:
a gate electrode;
an organic layer facing the gate electrode, and including a semiconductor;
source-drain electrodes electrically connected to the organic layer;
a protective layer configured of an insulating material, and covering the organic layer; and
a plurality of grains each of whose outside is covered with an affinity layer that has an affinity with the insulating material, the plurality of grains being dispersed in the protective layer.

13. A method of manufacturing an organic semiconductor device, the method comprising:
forming an organic layer including a semiconductor;
preparing ink by mixing an insulating material and grains into a solvent; and
forming a protective layer by covering the organic layer with the ink,
wherein outside of each of the grains is covered with an affinity layer that has an affinity with the insulating material.
